(19) United States
(12) Patent Application Publication
(10) Pub. No.: US 2016/0255295 A1
(43) Pub. Date: Sep. 1, 2016

(54) IMAGE SENSOR WITH ELECTRON MULTIPLICATION AND GROUPED READOUT OF PIXELS

(71) Applicant: E2V SEMICONDUCTORS, Saint Egreve (FR)

(72) Inventors: Pierre FEREYRE, Voreppe (FR); Frédéric MAYER, Voiron (FR)

(21) Appl. No.: 15/028,473

(22) PCT Filed: Oct. 9, 2014
(86) PCT No.: PCT/EP2014/071655

§ 371 Date: Apr. 11, 2016

(30) Foreign Application Priority Data
Oct. 14, 2013 (FR) 1359933

(51) Int. Cl. H04N 5/378; H01L 27/146

(52) U.S. Cl. CPC H04N 5/378; H01L 27/14643; H01L 27/14638

(57) ABSTRACT

The invention relates to image sensors allowing electronic images to be acquired at very low light levels.

The image sensor comprises pixels that can be read individually or, for greater sensitivity, after the charges of four adjacent pixels have been grouped. Two photodiodes of a given column (PH21, PH22) may transfer their charges to a given multiplication gate (GM1), the two pixels of the adjacent column transferring their charges to a second multiplication gate (GM2). A phase of multiplication may be achieved by applying an alternation of potentials in phase opposition to the multiplication gates. Read structures each associated with one of the multiplication gates allow the charges of each of the four photodiodes or the grouped charges of the four photodiodes to be read.

### FIELD

The invention relates to image sensors allowing electronic images to be acquired at very low light levels, especially for night vision, in which the energy level captured by the pixels is of the same order as the noise, shot noise in particular.

### BACKGROUND

To capture an image on a starry night with a signal/noise ratio of 10 dB, the number of photons captured by a pixel must be at least 40 photons. If it is desired to capture an image at a rate of 60 images per second, with an F/1 optical aperture and a signal-to-noise ratio of 10 dB, pixels having a large area (preferably about 100 square microns) are required. However, it is then difficult to prevent the sensor from saturating if the amount of light increases significantly, for example in the presence of artificial light sources.

It has therefore been proposed to use sensors having smaller pixels but employing a mode in which pixels are grouped so that at high light levels the sensor delivers one image point per pixel but at low light levels it delivers one image point per group of four adjacent pixels, the outputs of which are summed by analogue means and/or digitally.

It has also been proposed to use in these sensors electron multiplication systems that increase the ratio of the number of electrons produced by a pixel to the number of photons received by the pixel. These systems make use of electron motion in the semiconductor in which the electrons have been generated, acceleration voltages being applied such that secondary electrons are torn from the semiconductor and increase the initial number of electrons. The electron multiplication gain is proportional to the applied voltages and to the number of transfers (in general multiple back-and-forth trips between two semiconductor zones). Such sensors are for example described in patent applications EP 2 503 596 A and US 2008/0179495 A1.

### SUMMARY

The aim of the invention is to provide an image sensor structure that enables operation both with or without electron multiplication and operation with or without pixel grouping. One aim of the invention is also to ensure that at low light levels the sensor is able to employ a correlated double sampling operating mode reducing the kTC noise of the pixels even when a global shutter mode (as opposed to an electronic rolling shutter (ERS) mode) is used.

To achieve these goals, the invention provides a matrix image sensor comprising at least two rows of pixels and comprising means for reading the pixels either individually or after the charges originating from a group of four adjacent pixels belonging to two adjacent rows and two adjacent columns have been grouped together, characterized in that it comprises, for the group of four pixels:
for each pixel, a photodiode and a primary transfer gate allowing the charge generated by light in the photodiode to be transferred to the exterior of the photodiode;
two electron multiplication gates, the first multiplication gate being adjacent to the transfer gates of the two pixels of a first column and the second gate being adjacent to the primary transfer gates of the two other pixels of the group, belonging to the second column, and means for applying to the two multiplication gates an alternation of potentials in phase opposition;
first means for reading charge, comprising a first charge storage region and a first secondary transfer gate interposed between the first electron multiplication gate and the first charge storage region;
second means for reading charge, comprising a second charge storage region and a second secondary transfer gate interposed between the second electron multiplication gate and the second charge storage region;
and means for controlling the potentials applied to the transfer gates and to the multiplication gates, in order to execute a simple read mode and a grouped read mode, in which,
   in the simple read mode charges are transferred from the photodiodes of the two pixels of the first row to the first multiplication gate and to the second multiplication gate, respectively, then these charges are transferred from the multiplication gates to the first and second charge storage regions, respectively, and the charges present in these two regions are read by the first and second charge reading means, these operations then being repeated for the two pixels of the second row; and
   in the grouped read mode charges are transferred from the two pixels of the first column to the first multiplication gate and the charges of the two pixels of the second column are transferred to the second multiplication gate and, subsequently, the charges present under the multiplication gates are transferred to one of the storage regions, and the charge present in this region is read.

The means for applying an alternation of potentials in phase opposition to the two multiplication gates may optionally be used in the grouped read mode. They are not used in the simple read mode.

The two multiplication gates are preferably separated by an intermediate region held at a fixed potential during the electron multiplication. Preferably, this intermediate region is constructed as a photodiode having a fixed surface potential (i.e. a pinned diode). The intermediate region comprises an n-type diffusion region covered with a p-type semiconductor surface region maintained at a fixed potential. The fixed potential is preferably that of an active p-type layer in which the photodiodes are formed.

### BRIEF DESCRIPTION OF THE DRAWINGS

Other features and advantages of the invention will become apparent on reading the following detailed description which is given with reference to the appended drawings, in which:

FIG. 1 shows a conventional electrical diagram of an active pixel in MOS technology;

FIG. 2 shows a modified diagram incorporating an electron multiplication structure in the pixel;

FIG. 3 shows a schematic top view of a structure of four adjacent pixels according to the invention, the pixels may be read in a simple read mode or in a grouped read mode;

FIG. 4 shows a variant embodiment;

FIG. 5 shows another variant enabling different groups of four pixels to be grouped about a chosen pixel; and

FIG. 6 shows a lateral cross-sectional view of the structure in FIG. 3, along the line A-A in FIG. 3.

### DETAILED DESCRIPTION

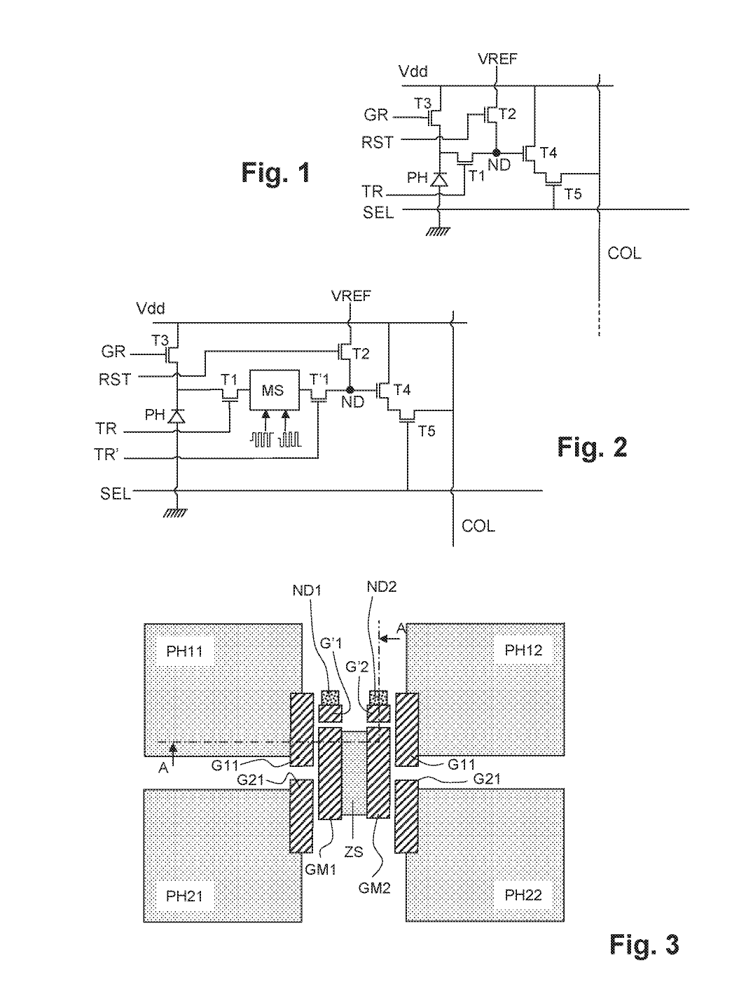

In order to allow the invention to be better understood, the electrical diagram of a conventional active five-transistor pixel of an image sensor in MOS technology has been reproduced in FIG. 1, and the diagram of an equivalent active pixel, this pixel however furthermore comprising electron multiplication means inside the pixel, has been reproduced in FIG. 2.

The pixel in FIG. 1 comprises a photodiode PH, a capacitive charge storage node ND (represented by a single point in FIG. 1 but in practice formed by an n-type diffusion region in the p-type layer), a transistor T1 for transferring charge between the cathode of the photodiode and the storage node, a transistor T2 for resetting the potential of the storage node, a transistor T3 for resetting the potential of the photodiode, a read transistor T4 in voltage-follower connection and a row selection transistor T5.

The transfer transistor T1 is controlled by a transfer signal TR. The transistor T2 has its drain connected to a reference potential VREF and is controlled by a reset control signal RST allowing the potential of the storage node to be reset. The transistor T3 is connected between the cathode of the photodiode and a reference potential that may be a supply potential Vdd. It is controlled by a reset signal GR allowing the potential of the photodiode to be reset. The follower transistor T4 has its drain connected to a fixed potential that may be the supply potential Vdd, its source connected to the row selection transistor T5, and its gate connected to the storage node ND. Lastly, the row selection transistor T5 has its gate connected to a row selection conductor that connects all the row selection transistors of a given row of pixels; this conductor is controlled by a row selection signal SEL specific to this row; the drain of the transistor T5 is connected to the source of the follower transistor and its source is connected to a column conductor COL common to all the pixels of a given column of pixels. This conductor allows a voltage representing the amount of charge on the storage node of a pixel selected by the row conductor SEL to be transmitted.

The column conductor is connected to a read circuit (not shown) specific to the column of pixels, at the bottom of this column.

The transfer transistor T1 shown in this diagram is in practice formed by a simple insulated transfer gate separating the photodiode from the storage node, this gate being controlled by a transfer signal TR that either allows electrons to pass or in contrast prevents their passage. Below, the expressions “transfer transistor” and “transfer gate” will both be used to refer to this type of structure.

FIG. 2 shows a schematic electrical diagram of a pixel in the case where the pixel comprises electron multiplication means inside the pixel. In this case, two transfer transistors (or gates) T1 and T′1 (rather than one) are located between the photodiode and the charge storage node ND, and an electron multiplication structure MS is located between these two transistors or gates. The first transfer gate, controlled by a control signal TR, makes it possible to pass photogenerated charge from the photodiode to the multiplication structure. The second transfer gate, controlled by a control signal TR′, allows electronic charge to be passed from the multiplication structure to the storage node ND.

In order to produce an image sensor structure that enables both operation with or without electron multiplication and operation with or without pixel grouping, the following solutions may be envisioned: two adjacent pixels of a given column transfer the charges gathered by their respective photodiodes, by way of two respective primary transfer gates, to the same first multiplication gate; the charges gathered by this multiplication gate may be multiplied by a multiplication structure that comprises at least this multiplication gate and a second multiplication gate; the multiplication (or absence of multiplication) terminates with intermediate storage under the second multiplication gate; the charge then contained under the second multiplication gate is read by a read structure (a secondary transfer gate for transferring the charge of the second multiplication gate to a charge storage node, a transistor for resetting this note, a follower transistor for copying the potential of the storage node, and a pixel selection transistor for outputting the potential of the follower transistor to a column conductor). This read structure is common to the two pixels of the column and it is located between these two pixels. It may be chosen to read the pixels in a simple mode, therefore in succession, by opening only one primary transfer gate, or in contrast to read the pixels in a grouped mode by requesting, simultaneously or in succession, the transfer of charge from the two photodiodes to the first multiplication gate. However, to group the signals of four adjacent pixels two-by-two rowwise and columnwise, it is necessary to digitize the signals originating from the read operation and then to carry out a digital summation of the results obtained from the pixels of two neighbouring columns.

It is also possible, starting with a structure similar to the preceding structure, to make provision for the charge gathered by the first photodiode to be transferred via a first primary transfer gate to the first multiplication gate and for the charge gathered by the second photodiode to be transferred via a second primary transfer gate to the second multiplication gate. The charges of two columnwise-adjacent pixels are therefore input into the multiplication structure via two separate channels. The electron multiplication terminates with intermediate storage under the first multiplication gate if it is desired to read the charge of the first pixel, but it terminates with charge storage under the second multiplication gate if it is desired to read the charge obtained from the second pixel. The electron multiplication may terminate with charge storage under either one of the multiplication gates if a grouped-mode readout is desired. In the grouped mode, charge is transferred in succession from one of the pixels to one side of the multiplication structure then from the other pixel to the other side of the multiplication structure. In this embodiment, there are two separate read structures, associated with each of the multiplication gates, for reading the charge stored under the first multiplication gate or under the second multiplication gate, respectively. Each read structure comprises a secondary transfer gate, a charge storage node, a reset transistor, a read transistor in voltage-follower connection and a row selection transistor. In the simple read mode of each pixel, as in the grouped read mode of two pixels, an electron multiplication may be performed. In the grouped read mode, the charges originating from adjacent pixels of a given column are grouped before being read and digitized, but to group the charges of four pixels it is necessary to group the charges and then digitally sum the result with the result of the readout of the signals of the two pixels of the neighbouring column.

In the sensor according to the invention, they multiplication structure is common to four adjacent pixels and may receive charge from these four pixels.

FIG. 3 shows a top view of an organisational schematic of a group of four columnwise- and rowwise-adjacent pixels, allowing, according to the invention, the pixels to be read in a simple read mode of each pixel or in a grouped read mode of four pixels, for an improved sensitivity, without a digital summation operation being required. The photodiodes, the transfer gates, the charge storage nodes, etc., are represented by simple rectangles in order to simplify the figure, but their geometrical shapes may be more complex in order to best fill the available space without increasing the pitch of the pixels or decreasing the optical aperture of the pixels. The electrical connections shown in the diagram in FIG. 2 are not shown.

A multiplication structure common to the four adjacent pixels is placed in a free space located between the four pixels. This structure makes it possible to perform an electron multiplication in the case where a grouped-mode readout of the electrons accumulated by the four pixels is carried out.

Each of the four pixels comprises a respective photodiode, PH11 and PH12 for the two pixels of a first row and PH21 and PH22 for the pixels of the second row. The pixels PH11 and PH21 belong to a first column and the pixels PH12, PH22 belong to the second column.

A primary transfer gate G11 (playing the role of the transistor T1 in FIG. 2) is adjacent on one side to the photodiode PH11 and on the other to a first multiplication gate GM1 of the multiplication structure associated with the group of four pixels. The primary transfer gate G11 allows charge to be transferred from the first photodiode PH11 to the multiplication structure; this charge arrives via the first multiplication gate.

A second primary transfer gate G21 is adjacent on one side to the photodiode PH21 and on the other to the same first multiplication gate GM1. It allows charge to be transferred from the photodiode PH21 to the first multiplication gate.

Symmetrically, for the two photodiodes of the second column, two other primary transfer gates G12 and G22 are adjacent on one side to these two photodiodes, PH21 and PH22 respectively, and on the other side to a second multiplication gate GM2 of the multiplication structure. They allow charges to be transferred from these two other photodiodes to the second multiplication gate.

The multiplication structure may comprise, in its preferred version, two gates GM1 and GM2 and potential switching means for alternately passing one of the gates to a high potential while the other gate is at a low potential and vice versa. The electron multiplication coefficient obtained with this structure depends on the potentials applied and on the number of alternations applied.

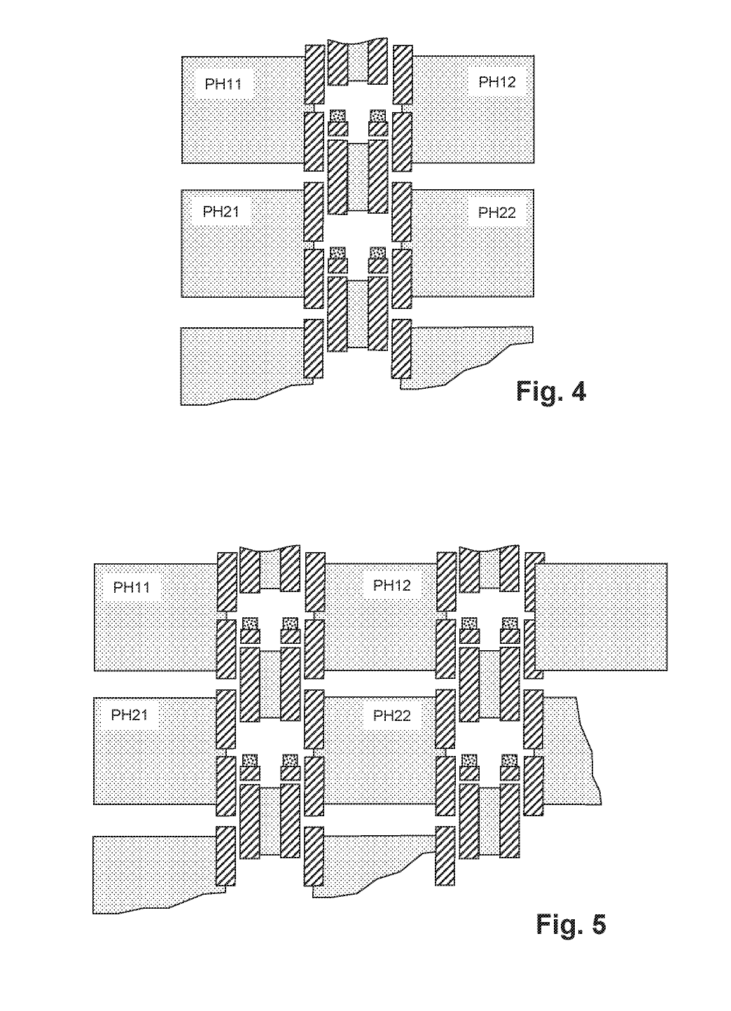

Preferably, the multiplication gates are separated by an intermediate semiconductor zone ZS kept at a constant potential intermediate between the high and low potentials applied to the gates. During a multiplication operation, packets of electrons, which transit alternately from the first multiplication gate to the second, and vice versa, pass through this intermediate zone. This mechanism for multiplying electrons under the effect of alternations of potentials applied to the multiplication gates on either side of the intermediate zone ZS is illustrated in detail in the aforementioned European patent application EP 2 503 596, notably with regard to its FIG. 4.

The four-pixel structure according to the invention contains two other charge reading structures, one associated with the first multiplication gate GM1 and the other with the second multiplication gate GM2, respectively. These read structures serve to read the charge stored under the first multiplication gate and the charge stored under the second multiplication gate, respectively.

The first read structure comprises a charge storage node ND1, a secondary transfer gate G′1 adjacent both to the first multiplication gate and to the storage node ND1. This secondary transfer gate allows the electrons present under the first multiplication gate, which may or may not have undergone a multiplication step, to be transferred to the storage node. The first read structure furthermore comprises the following elements: a transistor (not shown) for resetting the potential of the storage node ND1 and formed in the same way as the transistor T2 of a conventional active pixel; a read transistor in voltage-follower connection formed in the same way as the read transistor T4 of a conventional active pixel; and a row selection transistor formed and connected in the same way as the selection transistor T5 of a conventional active pixel. All these elements form part of the first read structure, which is associated with the two pixels of the first column, i.e. with the photodiodes PH11 and PH21.

The second read structure is associated with the two other pixels belonging to the second column, therefore with the photodiodes PH12 and PH22. It is identical to the first structure and functions in the same way. It comprises a charge storage node ND2, a secondary transfer gate G′2 adjacent to the second multiplication gate GM2 and to the storage node ND2. It also comprises, in the same way as the first structure, the following elements (not shown): a transistor for resetting the second storage node, a follower read transistor and a row selection transistor.

The row selection transistors of the two structures are controlled simultaneously by the same row conductor.

The structure may function in a simple read mode or a grouped read mode.

In the simple read mode, an electronic rolling shutter (ERS) mode is used, i.e. the charge integration time is identical for the various rows but offset in time from one row to the following; the photodiodes integrate charge from the end of the preceding integration cycle, the integration period starting at the end of a transfer of charge out of the photodiode and terminating for each row at the end of a new transfer of charge out of the photodiode; the instants of transfer are offset from one row to the following;
a) during this integration, the potential of the storage nodes of the selected row is reset, for example the nodes ND1, ND2 of the first row (photodiodes PH11 and PH12);
b) the reset level of these nodes is read;
c) at the end of the integration time, the charges of the pixels of the first row (photodiodes PH11 and PH12) are transferred, by way of the primary transfer gates G11 and G12, to under the multiplication gates GM1 and GM2, respectively; for this purpose, the multiplication gates GM1 and GM2 are raised to a sufficiently high potential relative to the intrinsic potential of the photodiode;
d) the charge stored under the multiplication gate GM1 is transferred to the storage node ND1, by way of the secondary transfer gate G′1, and, simultaneously or in succession, the charge stored under the multiplication gate GM2 is transferred to the storage node ND2, by way of the secondary transfer gate G′2; the intrinsic potential of the zone ZS forms a potential barrier in order to prevent the charges present under the gates GM1 and GM2 from mixing;
e) the potential of the storage nodes ND1 and ND2, representing the amount of light received by the photodiodes PH11 and PH12, respectively, is read; and
f) the operations a) to e) are repeated for the following row comprising the photodiodes PH21 and PH22, by opening the primary transfer gates G21 and G22 in step c) and using the same multiplication gates, the same secondary transfer gates G′1 and G′2 and the same storage nodes ND1 and ND2 as above;

then the same operations are carried out for the pairs of rows of following rank.

Alternatively, a half-frame readout could be carried out by first reading all the rows of photodiodes of uneven rank then all the rows of even rank.

In this simple read mode, the multiplication gates were used as simple intermediate storage gates between the photodiodes and storage nodes.

In a grouped read mode, the charges of the four photodiodes PH11, PH12, PH21, PH22 are gathered in the multiplication structure, these charges are multiplied, stored under one of the two multiplication gates and read by the read structure associated with this multiplication gate, for example the read structure comprising G′1 and ND1 if it is a question of the first multiplication gate GM1.

The read procedure then proceeds as follows: the four photodiodes integrate charges, preferably in a global shutter mode in which the instant at which charge integration starts and the instant at which charge integration ends is the same for all the photodiodes; this time is optionally adjustable if there is a transistor (such as T3 in FIG. 2) for resetting the potential of each photodiode, this transistor being controlled simultaneously for all the photodiodes;
a) during this integration, the potential of the storage nodes ND1 and ND2 is reset; at the same time, the other groups of four pixels are reset;
b) at the end of the integration period, charge is transferred from the photodiodes via the primary transfer gates G11, G12, G21,

G22; the charges of the photodiodes of the first column (PH11 and PH21) are transferred to under the multiplication gate GM1; the charges of the two other photodiodes (PH12 and PH22) are transferred at the same time or immediately afterwards to under the multiplication gate GM2;
c) an electron multiplication is optionally performed by applying an alternation of potentials in phase opposition to the multiplication gates GM1 and GM2; the multiplication or absence of multiplication is terminated by storing the multiplied charges under one of the two multiplication gates, for example the gate GM1; the phase opposition is non-overlapping insofar as the two gates must not simultaneously be at the low potential; it may be preferable, for this purpose, for the high levels of the potentials to overlap slightly; and
d) for a pair of rows, using the read structure associated with this pair, the reset level of the storage node ND1 or ND2 (i.e. that to which the charge is transferred) is read; then the charge stored under the multiplication gate (here G1) is transferred to the corresponding storage node (ND1), and the level of the potential of this node is read; the procedure is restarted for the other pairs of rows.
Therefore, in this mode the sum of the charges of four photodiodes is read, these charges being mixed and multiplied in the multiplication structure (GM1, ZS, GM2).

In the grouped read mode it is possible to benefit both from global shutter operation and a correlated double sampling readout in which the storage node is reset and read before charge is transferred to this storage node and read. In the simple read mode it is necessary to use an ERS (rolling shutter) operating mode.

In the embodiment in FIG. 3, there is one row of multiplication structures and of read structures for two rows of photodiodes. In a variant embodiment shown in FIG. 4, provision may be made for there to be as many rows of multiplication structures as there are rows of photodiodes, but there is, as shown in FIG. 3, only one multiplication structure common to two pixels belonging to adjacent rows. Therefore, in this case each photodiode has two primary transfer gates allowing charge to be transferred to either one of two multiplication structures belonging to two adjacent rows. However, this embodiment takes up more space than the embodiment in FIG. 3. It will be noted that it is possible to operate the sensor in a global shutter mode by simultaneously actuating all the transfer gates that have the same position relative to the photodiodes. It is possible with the embodiment in FIG. 4 to carry out a simple read operation without multiplication, or a grouped read operation of four pixels with or without multiplication.

As a variant of FIGS. 3 and 4, provision could be made, as is for example shown in FIG. 5, for there to be one multiplication structure on each side of the photodiode. There is therefore then, in one row of multiplication structures, as many multiplication structures as there are columns of photodiodes. If this arrangement is combined with that in FIG. 4, the arrangement in FIG. 5 is obtained, there being, in this arrangement, four primary transfer gates for each photodiode, these gates allowing charge to be transferred to one of four multiplication structures belonging to two adjacent rows and two adjacent columns, respectively.

This makes it possible, in the grouped read mode, to choose the adjacent pixels to be grouped. This embodiment is also less compact than that in FIG. 3.

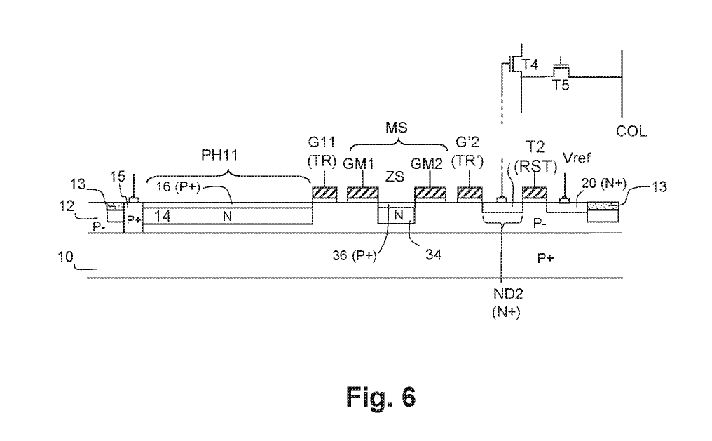

FIG. 6 shows a technological cross section of the pixel, showing one practical way of producing the sensor according to the invention. FIG. 6 is a lateral cross section along the line A-A in FIG. 3. This line A-A passes through the photodiode PH11, the primary transfer gate G11, the multiplication gate GM1, the pinned intermediate semiconductor zone ZS, the secondary transfer gate G′2, and the storage node ND2. FIG. 6 also shows elements that are not shown in FIG. 3, namely a transistor for resetting the storage node ND2, i.e. the transistor T2 in FIG. 2; lastly, the electrical connection, according to the schematic diagram in FIG. 2, between the storage node ND2 and two transistors T4 and T5 (follower transistor and row selection transistor connected to a column conductor COL) has been recalled. The transistor for resetting the photodiode PH11 (transistor T3 in FIG. 2) is not shown; it comprises a control gate allowing the charge of the photodiode to be transferred to a drain (not shown) at the start of an integration period.

The pixel is formed on a substrate 10 that preferably comprises a weakly p-doped or p⁻-doped (the p⁻ symbol is used to designate this weak doping) semiconductor active layer 12 formed on the surface of a more strongly doped (p⁺) layer. The pixel is isolated from the neighbouring pixels by an isolating barrier 13 that completely encircles it. This barrier may be a shallow trench isolation above a p-type well.

The pixel comprises the photodiode region PH11 the perimeter of which follows the outline of an n-type semiconductor region 14 implanted in a portion of the depth of the active layer 12. This implanted region is surmounted by a p⁺-type surface region 16 that is kept at a zero reference potential. It is a question of a pinned photodiode (i.e. the potential of the p⁺-type surface region is fixed). The zero reference potential is that applied to the p⁻-type active layer. In the simplest case, it is the potential of the p⁺-type substrate located under the active layer and applying its own potential to the active layer; the surface region 16 is for example kept at this zero potential because the region 16 touches a deep p⁺-type diffusion region 15 that makes contact with the substrate 10. Electrical contact can also be made to this diffusion region 15 in order to apply, via this contact, a zero potential to the region 16.

The charge storage node ND2 is an n-type diffusion region in the active layer 12. A contact is formed on the storage node, in order to allow the potential of this region to be applied to the gate of a follower transistor (T4), in order to transform the amount of charge held by the storage node into an electrical voltage level.

The gate of the transistor T2 allows charge to be emptied from the storage node into an evacuation drain 20 that is an n⁺-type region connected to a positive reset potential Vref.

The multiplication structure MS comprises the insulated gates GM1 and GM2 separated by the semiconductor zone ZS. This zone is formed, in the same way as the photodiode (but not necessarily with the same doping density) by an n-type region 34 diffused into the active layer 12, this region being covered by a p⁺-type surface region 36. This region 36 is for example kept at the zero reference potential because it touches (not shown in FIG. 6) a deep p⁺-type region that makes contact with the substrate, analogously to the region 15 that touches the region 16 of the photodiode. The region ZS is at an internal built-in potential fixed by keeping the region 36 at the reference potential of the active layer 12, here that of the substrate 10.

The primary transfer gate G11 is a gate insulated from the active layer 12; it is located between the photodiode PH11 and the multiplication gate GM1 and it allows charge to be transferred from the photodiode to the gate GM1.

The secondary transfer gate G′2 is an insulated gate located between the multiplication gate GM2 and the storage node ND2.

The multiplication gates GM1 and GM2 are also gates that are insulated from the active layer. They are separated from the gate G11 and gate G′2, respectively, by a narrow interval (as narrow as possible given the technology used) in which the semiconductor may not have a specific doping, i.e. it may be directly made up of the active layer 12.

Potential switching means are provided for applying directly to the multiplication gates GM1 and GM2 high potentials (higher than zero) or low potentials (lower than zero) depending on the transfer or amplification phase in question. These switching means are not shown because they are not located in the pixel.

To transfer charges from the photodiode to the multiplication gate GM1, the potential present under this gate and under the primary transfer gate G11 is lowered by increasing their potential. The pinned zone ZS forms a potential barrier that prevents the passage of these charges to the gate GM2.

For the charge multiplication, a multiplicity (several tens, hundreds or even thousands) of alterations of potentials in phase opposition are applied to the gates GM1 and GM2 while leaving the zone ZS at a potential intermediate between a high potential and a low potential of this alternation. The charge stored under the gate GM1 is alternately switched from the gate GM1 to the gate GM2 and vice versa. The electric fields seen by the electrons are sufficiently high to accelerate the electrons and thus create electron/hole pairs and therefore additional electrons in each alternation. The electron gain during one alternation is very low but it is multiplied by the number of alternations. The potential of the primary and secondary transfer gates is a low potential during the multiplication, creating a potential barrier preventing the charge from exiting the multiplication structure and confining this charge alternately under the gate GM1 and under the gate GM2.

At the end of the multiplication, the charge remains stored under the gate GM2 if the alternation is stopped when the gate GM2 has a high potential; it could in the contrary case remain stored under the gate GM1. If the charge remains under the gate GM2, the secondary transfer gate G′2 is temporarily raised to a high potential allowing the charge to be passed to the storage node ND2 with a view to reading this charge with the transistors T4 and T5 using a conventional read process.

1. A matrix image sensor comprising at least two rows of pixels and comprising means for reading the pixels either individually or after the charges originating from a group of four adjacent pixels belonging to two adjacent rows and two adjacent columns have been grouped together, comprising, for the group of four pixels:
for each pixel, a photodiode and a primary transfer gate allowing the charge generated by light in the photodiode to be transferred to the exterior of the photodiode;
two electron multiplication gates, the first multiplication gate being adjacent to the transfer gates of the two pixels of a first column and the second gate being adjacent to the primary transfer gates of the two other pixels of the group, belonging to the second column, and means for applying to the two multiplication gates an alternation of potentials in phase opposition;
first means for reading charge, comprising a first charge storage region and a first secondary transfer gate interposed between the first electron multiplication gate and the first charge storage region;
second means for reading charge, comprising a second charge storage region and a second secondary transfer gate interposed between the second electron multiplication gate and the second charge storage region;
and means for controlling the potentials applied to the transfer gates and to the multiplication gates, in order to execute a simple read mode and a grouped read mode, in which,
in the simple read mode charges are transferred from the photodiodes of the two pixels of the first row to the first multiplication gate and to the second multiplication gate, respectively, then these charges are transferred from the multiplication gates to the first and second charge storage regions, respectively, and the charges present in these two regions are read by the first and second charge reading means, these operations then being repeated for the two pixels of the second row; and
in the grouped read mode charges are transferred from the two pixels of the first column to the first multiplication gate and the charges of the two pixels of the second column are transferred to the second multiplication gate and, subsequently, the charges present under the multiplication gates are transferred to one of the storage regions, and the charge present in this region is read.

2. The sensor of claim 1, wherein the two multiplication gates are separated by an intermediate region held at a fixed potential during the electron multiplication.

3. The sensor of claim 2, wherein the intermediate region is an n-type diffusion region covered with a p-type surface region maintained at a fixed potential.

4. The sensor of claim 1, comprising a row of multiplication structures for each row of pixels, and in that there are, for each photodiode, two primary transfer gates allowing charges to be transferred to one or other of two multiplication structures belonging to two adjacent rows.

5. The sensor of claim 4, comprising a column of multiplication structures for each column of pixels, and in that there are, for each photodiode, four primary transfer gates allowing charges to be transferred to one of four multiplication structures belonging to two adjacent rows and two adjacent columns, respectively.
